(19) United States
(12) Patent Application Publication
(10) Pub. No.: US 2026/0164678 A1
(43) Pub. Date: Jun. 11, 2026

(54) 3D MEMORY DEVICE AND METHOD OF IMPLEMENTING MULTI-LEVEL MEMORY USING THE SAME

(71) Applicant: Samsung Electronics Co., Ltd., Suwon-si (KR)

(72) Inventors: Changseung LEE, Suwon-si (KR); Youngjae KANG, Suwon-si (KR); Sangwook KIM, Suwon-si (KR); Hajun SUNG, Suwon-si (KR); Kiyeon YANG, Suwon-si (KR); Jooho LEE, Suwon-si (KR); Minwoo CHOI, Suwon-si (KR)

(73) Assignee: Samsung Electronics Co., Ltd., Suwon-si (KR)

(21) Appl. No.: 19/182,054

(22) Filed: Apr. 17, 2025

(30) Foreign Application Priority Data
Aug. 22, 2024 (KR) 10-2024-0113098

(51) Int. Cl. H10B 63/00; G11C 5/06; G11C 13/00; H10N 70/00

(52) U.S. Cl. CPC H10B 63/845; G11C 5/063; G11C 13/0097; H10B 63/24; H10N 70/823; H10N 70/8822; H10N 70/8825; H10N 70/8828

(57) ABSTRACT

A 3D memory device may include a plurality of memory cells arranged in three dimensions on a substrate. Each of the plurality of memory cells may include a transistor and a plurality of self-selecting memory layers connected to the transistor. The transistor may include at least one channel layer parallel to the substrate. Each of the plurality of self-selecting memory layers may include a chalcogenide-based material having Ovonic threshold switching characteristics. A threshold voltage of the chalcogenide-based material may change according to a polarity and an intensity of an applied voltage. The plurality of self-selecting memory layers may be configured to have different threshold voltages from each other, so that each of the plurality of memory cells may implement a multilevel memory.

### CROSS-REFERENCE TO RELATED APPLICATION

This application claims the benefit of Korean Patent Application No. 10-2024-0113098, filed on Aug. 22, 2024 in the Korean Intellectual Property Office, the disclosure of which is incorporated herein in its entirety by reference.

### BACKGROUND

### 1. Field

The disclosure relates to a three-dimensional (3D) memory device and/or a method of implementing a multilevel memory by using the same.

### 2. Description of the Related Art

As miniaturization, multi-function, and high performance of electronic devices may be required, technology for increasing the degree of integration of high-capacity semiconductor memory devices may be required. In the case of two-dimensional (2D) semiconductor memory devices, the degree of integration mainly may be determined by the area occupied by each memory cell, and thus, there may be a limit to increasing the degree of integration. Accordingly, three-dimensional (3D) semiconductor memory devices in which memory cells are arranged in three dimensions have been proposed.

### SUMMARY

Provided are a three-dimensional (3D) memory device and/or a method of implementing a multilevel memory using the same.

Additional aspects will be set forth in part in the description which follows and, in part, will be apparent from the description, or may be learned by practice of the presented embodiments.

According to an example embodiment of the disclosure, a 3D memory device may include a plurality of memory cells arranged in three dimensions on a substrate. Each of the plurality of memory cells may include a transistor and a plurality of self-selecting memory layers connected to the transistor. The transistor may include at least one channel layer parallel to the substrate. Each of the plurality of self-selecting memory layers may include a chalcogenide-based material having Ovonic threshold switching characteristics. A threshold voltage of the chalcogenide-based material may change according to a polarity and an intensity of an applied voltage. The plurality of self-selecting memory layers may be configured to have different threshold voltages from each other, so that each of the plurality of memory cells may implement a multilevel memory.

In some embodiments, the transistor may further include at least one gate electrode on the at least one channel layer, and at least one gate insulating layer between the at least one channel layer and the at least one gate electrode.

In some embodiments, each of the plurality of self-selecting memory layers may include a chalcogen element including at least one of Se, Te, and S, and at least one of Ge, As, and Sb.

In some embodiments, the plurality of self-selecting memory layers may be connected to the transistor in parallel or in series.

In some embodiments, the plurality of self-selecting memory layers may include a first self-selecting memory layer having a first reset threshold voltage, and a second self-selecting memory layer having a second reset threshold voltage. A magnitude of the second reset threshold voltage may be higher than a magnitude of the first reset threshold voltage.

In some embodiments, the plurality of memory cells may be configured to implement multilevel resistance states by changing a voltage applied to each of the first self-selecting memory layer and the second self-selecting memory layer.

In some embodiments, the plurality of memory cells may be configured to implement multilevel resistance states by changing the voltage applied to each of the first self-selecting memory layer and the second self-selecting memory layer to a voltage with a magnitude lower than the magnitude of the first reset threshold voltage, a voltage between the first reset threshold voltage and the second reset threshold voltage, and a voltage with a magnitude higher than the magnitude of the second reset threshold voltage. The first reset threshold voltage may be between the second reset threshold voltage and the voltage with the magnitude less than the magnitude of the first reset threshold voltage. The second reset threshold voltage may be between the first reset threshold voltage and the voltage with the magnitude higher than the magnitude of the second reset threshold voltage.

In some embodiments, the 3D memory device may further include a plurality of bit lines extending perpendicular to the substrate. The plurality of memory cells may be arranged perpendicular to the substrate along the plurality of bit lines.

In some embodiments, the 3D memory device may further include a plurality of word lines extending parallel to the substrate and intersecting the plurality of bit lines.

In some embodiments, the 3D memory device may further include a plurality of bit lines extending perpendicular to the substrate; and a plurality of select lines on the substrate. The plurality of select lines may be configured to select a selected bit line among the plurality of bit lines.

According to an example embodiment of the disclosure, an electronic apparatus may include the 3D memory device described above.

According to an example embodiment of the disclosure, a method of implementing a multilevel memory by using a 3D memory device is provided. The 3D memory device may include a plurality of memory cells arranged in three dimensions on a substrate. The method may include implementing multi-level resistance states by changing a voltage applied to a plurality of self-selecting memory layers in the plurality of memory cells. Each of the plurality of memory cells may include the plurality of self-selecting memory layers connected to a transistor. The transistor may include at least one channel layer parallel to the substrate. Each of the plurality of self-selecting memory layers may include a chalcogenide-based material having Ovonic threshold switching characteristics. A threshold voltage of the chalcogenide-based material may change according to a polarity and an intensity of an applied voltage.

In some embodiments, the plurality of self-selecting memory layers may be connected to the transistor in parallel or in series.

In some embodiments, the plurality of self-selecting memory layers may be configured to have different threshold voltages from each other.

In some embodiments, the plurality of self-selecting memory layers may include a first self-selecting memory layer having a first reset threshold voltage and a second self-selecting memory layer having a second reset threshold voltage. A magnitude of the second reset threshold voltage may be higher than a magnitude of the first reset threshold voltage.

In some embodiments, the multi-level resistance states may be implemented by changing a voltage applied to each of the first self-selecting memory layer and the second self-selecting memory layer to a voltage with a magnitude lower than the magnitude of first reset threshold voltage, a voltage between the first reset threshold voltage and the second reset threshold voltage, or a voltage with a magnitude higher than the magnitude of the second reset threshold voltage. The first reset threshold voltage may be between the second reset threshold voltage and the voltage with the magnitude less than the magnitude of the first reset threshold voltage. The second reset threshold voltage may be between the first reset threshold voltage and the voltage with the magnitude higher than the magnitude of the second reset threshold voltage.

In some embodiments, the transistor may further include at least one gate electrode on the at least one channel layer and at least one gate insulating layer between the at least one channel layer and the at least one gate electrode.

In some embodiments, the 3D memory device may further include a plurality of bit lines extending perpendicular to the substrate. The plurality of memory cells may be arranged perpendicular to the substrate along the plurality of bit lines.

In some embodiments, the 3D memory device may further include a plurality of word lines extending parallel to the substrate and intersecting the plurality of bit lines.

In some embodiments, the 3D memory device may further include a plurality of bit lines extending perpendicular to the substrate. The 3D memory device may further include a plurality of select lines on the substrate. The plurality of select lines may be configured to select a selected bit line among the plurality of bit lines.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic perspective view of a three-dimensional (3D) memory device according to an embodiment;

FIG. 2 is a cross-sectional view of a memory cell illustrated in FIG. 1;

FIG. 3 is a graph showing an example of voltage-current characteristics of a self-selecting memory layer illustrated in FIG. 2;

FIG. 4A is a graph showing an example of a bias voltage for a set SET operation and a read operation applied to the self-selecting memory layer illustrated in FIG. 2;

FIG. 4B is a graph showing an example of a bias voltage for a reset RESET operation and a read operation applied to the self-selecting memory layer illustrated in FIG. 2;

FIG. 5 is a graph showing an example of voltage-current characteristics according to a magnitude (intensity) of a writing voltage applied to the self-selecting memory layer illustrated in FIG. 2;

FIG. 6 is a graph showing changes in a reset threshold voltage RESET Vth and a set threshold voltage SET Vth, according to a writing voltage applied to a memory layer in a memory device according to an embodiment;

FIG. 7 is a schematic view of an example of a circuit diagram of a 3D memory device according to an embodiment;

FIG. 8 is a schematic view of another example of a circuit diagram of a 3D memory device according to an embodiment;

FIGS. 9A and 9B illustrate example structures of a transistor applicable to a memory cell of a 3D memory device according to an embodiment;

FIGS. 10A and 10B illustrate other example structures of a transistor applicable to a memory cell of a 3D memory device according to an embodiment;

FIG. 11 is a schematic circuit diagram of a 3D memory device according to another embodiment;

FIG. 12 is a graph showing a voltage Vdd/2 applied to each of first and second self-selecting memory layers illustrated in FIG. 11, in four states;

FIGS. 13A to 13D illustrate resistances of the first and second self-selecting memory layers in four states illustrated in FIG. 12;

FIG. 14 is a schematic circuit diagram of a 3D memory device according to another embodiment;

FIG. 15 is a graph showing a voltage Vdd applied to each of the first and second self-selecting memory layers illustrated in FIG. 14, in four states;

FIGS. 16A to 16D illustrate resistances of the first and second self-selecting memory layers in four states illustrated in FIG. 15;

FIG. 17 is a conceptual view schematically showing a device architecture applicable to an exemplary electronic apparatus;

FIG. 18 is a block diagram of a memory system according to an embodiment; and

FIG. 19 is a block diagram showing a neuromorphic apparatus according to an embodiment and an external device connected thereto.

### DETAILED DESCRIPTION

Reference will now be made in detail to embodiments, examples of which are illustrated in the accompanying drawings, wherein like reference numerals refer to like elements throughout. Throughout the drawings, sizes of components in the drawings may be exaggerated for convenience of explanation and clarity. Furthermore, as embodiments described below are examples, other modifications may be produced from the embodiments. In this regard, the embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items.

As used herein, the singular forms “a,” “an” and “the” are intended to include the plural forms as well, unless the context clearly indicates otherwise. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Furthermore, when a constituent element is disposed “above” or “on” to another constituent element, the constituent element may be only directly on the other constituent element or above the other constituent elements in a non-contact manner. As used herein, the singular forms “a,” “an,” and “the” are intended to include the plural forms as well, unless the context clearly indicates otherwise. Furthermore, it will be further understood that the terms “comprises” and/or “comprising” used herein specify the presence of stated features or elements, but do not preclude the presence or addition of one or more other features or elements.

The use of the terms “a,” “an,” “the,” and similar referents in the context of describing the disclosure is to be construed to cover both the singular and the plural. Also, the operations of all methods described herein can be performed in any suitable order unless otherwise indicated herein or otherwise clearly contradicted by context. The disclosure is not limited to the described order of the steps.

Furthermore, terms such as “. . . portion,” “. . . unit,” “. . . module,” and “. . . block” stated in the disclosure may signify a unit to process at least one function or operation and the unit may be embodied by hardware, software, or a combination of hardware and software.

Furthermore, the connecting lines, or connectors shown in the various figures presented are intended to represent functional relationships and/or physical or logical couplings between the various elements. It should be noted that many alternative or additional functional relationships, physical connections or logical connections may be present in a practical device.

The use of any and all examples, or language (e.g., “such as”) provided herein, is intended merely to better illuminate the disclosure and does not pose a limitation on the scope of the disclosure unless otherwise claimed.

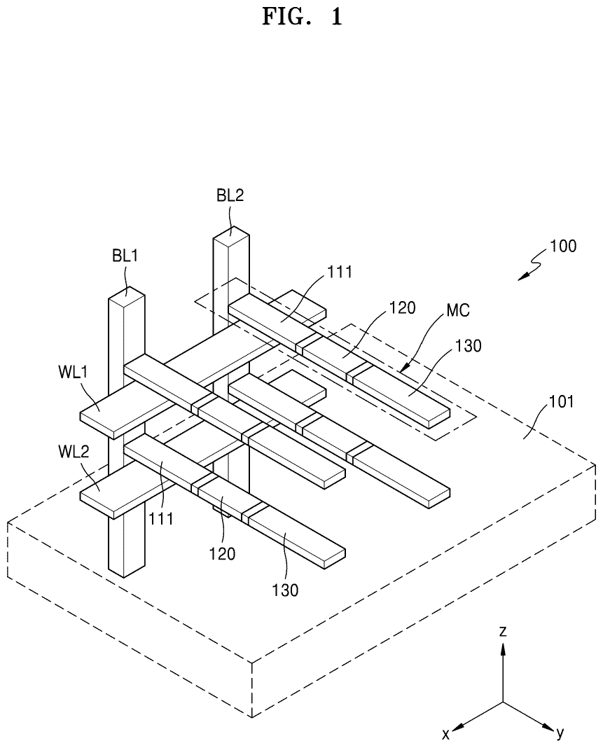

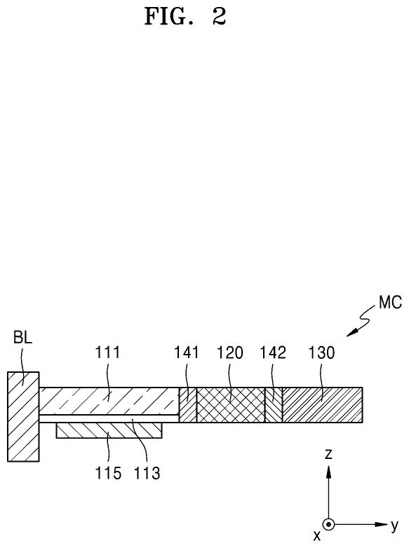

FIG. 1 is a schematic perspective view of a three-dimensional (3D) memory device 100 according to an embodiment. FIG. 2 is a cross-sectional view of a memory cell MC illustrated in FIG. 1.

Referring to FIGS. 1 and 2, the 3D memory device 100 may include a plurality of memory cells MC arranged in three dimensions on a substrate 101. The substrate 101 may include various materials. For example, the substrate 101 may include a single-crystal silicon substrate, a compound semiconductor substrate, or a silicon on insulator (SOI) substrate, but the disclosure is not limited thereto. Furthermore, the substrate 101 may further include, for example, an impurities region by doping, an electronic device such as a transistor, and/or a periphery circuit for selecting and controlling memory cells.

A plurality of bit lines BL1 and BL2 extend on the substrate 101 in a direction (e.g., z-axis direction) that is perpendicular to the substrate 101, and the memory cells MC are arranged in a direction perpendicular to the substrate 101 along the bit lines BL1 and BL2. Each of the memory cells MC extends perpendicularly to each of the bit lines BL1 and BL2. A plurality of word lines WL1 and WL2 extend in a direction (e.g., an x-axis direction) parallel to the substrate 101 to intersect the bit lines BL1 and BL2. One end portion of each of the memory cells MC is electrically connected to a corresponding one of the bit lines BL1 and BL2, and each of the bit lines BL1 and BL2 may function of applying a voltage to each of the memory cells MC.

Each of the memory cells MC may include a transistor connected to each of the bit lines BL1 and BL2 and a self-selecting memory layer 120 connected to the transistor. The transistor and the self-selecting memory layer 120 are connected to each other in series.

The transistor may include a channel layer 111, a gate electrode 115, and a gate insulating layer 113. The channel layer 111 may extend parallel to the substrate 101. The channel layer 111 may extend in a direction parallel to the substrate 101, for example, in a y-axis direction. One end portion of the channel layer 111 may be electrically connected to each of the bit lines BL1 and BL2, and the other end portion of the channel layer 111 may be electrically connected to the self-selecting memory layer 120.

The channel layer 111 may include a semiconductor material. The channel layer 111 may include, for example, Si, Ge, SiGe, Group III-V semiconductors, or the like. As a detailed example, the channel layer 111 may include poly-Si, but the disclosure is not limited thereto. Furthermore, the channel layer 111 may include, for example, an oxide semiconductor, a nitride semiconductor, an oxynitride semiconductor, a two-dimensional (2D) semiconductor material, quantum dots, or an organic semiconductor. The oxide semiconductor may include, for example, InGaZnO, or the like, the 2D semiconductor material may include, for example, transition metal dichalcogenide (TMD) or graphene, and the quantum dots may include colloidal quantum dots (colloidal QD), a nanocrystal structure, or the like. However, this is just an example, and the disclosure is not limited thereto.

The channel layer 111 may further include a dopant. The dopant may include a p-type dopant or an n-type dopant. The p-type dopant may include, for example, Group III elements, such as B, Al, Ga, or In, and the n-type dopant may include, for example, Group V elements, such as P, As, or Sb.

The gate electrode 115 may be provided on one surface of channel layer 111. FIGS. 1 and 2 illustrate an example in which the gate electrode 115 is provided on a lower surface of the channel layer 111. However, the disclosure is not limited thereto, and the gate electrode 115 may be provided on an upper surface of the channel layer 111. The gate electrode 115 controls the channel layer 111, and the word lines WL1 and WL2 may be electrically connected to the gate electrode 115. The gate electrode 115 may be integrally formed with the word lines WL1 and WL2. A voltage to turn on/off the channel layer 111 may be selectively applied to the gate electrode 115 through the word lines WL1 and WL2.

The gate electrode 115 may include a metal material, metal nitride, impurity-doped silicon, or a 2D conductive material which has excellent conductivity. However, this is just an example, and the gate electrode 115 may include various other materials. The gate insulating layer 113 is arranged between gate electrode 115 and the channel layer 111. The gate insulating layer 113 may include various types of insulating materials, and for example, silicon oxide, silicon nitride, or silicon oxynitride may be used for the gate insulating layer 113.

The self-selecting memory layer 120 is connected in series to the transistor including the channel layer 111, the gate electrode 115, and the gate insulating layer 113. One end portion of the channel layer 111 may be electrically connected to each of the bit lines BL1 and BL2, and the other end portion of the channel layer 111 may be electrically connected to the self-selecting memory layer 120.

The self-selecting memory layer 120 may have Ovonic threshold switching (OTS) characteristics of having a high resistance state when an input voltage is lower than a threshold voltage and having a low resistance state when the input voltage is higher than the threshold voltage. Furthermore, the self-selecting memory layer 120 may have memory properties in which a threshold voltage is shifted according to the polarity and the intensity of an applied bias voltage. Accordingly, the self-selecting memory layer 120 may have properties to perform both of a memory function and a selector function.

The self-selecting memory layer 120 may include a Chalcogenide-based material. For example, the self-selecting memory layer 120 may include a chalcogen element and at least one of Ge, As, and Sb, the chalcogen element comprising at least one of Se, Te, and S. The self-selecting memory layer 120 may further include at least one of In, Al, C, B, Sr, Ga, O, N, Si, Ca, and P. For example, the self-selecting memory layer 120 may include at least one of GeAsSe, GeAsSeIn, GeAsSeSIn, GeAsSeSb, GeAsSeTe, GeAsSeAl, GeAsSeAlIn, GeSbSe, GeAsSeGa, GeSe, GeSeIn, GeS, GeSIn, GeCTe, GeCTeN, and GeSbSeN.

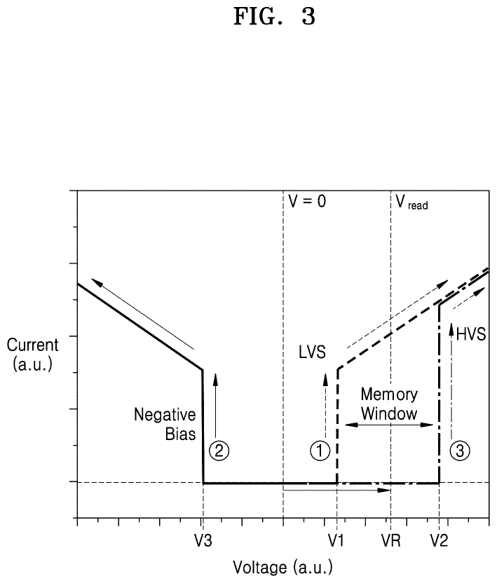

FIG. 3 is a graph showing an example of the voltage-current characteristics of the self-selecting memory layer 120 illustrated in FIG. 2.

Referring to FIG. 3, the self-selecting memory layer 120 may have any one state between a first state (low Vth state; LVS) in which a threshold voltage is relatively low and a second state (high Vth state; HVS) in which the threshold voltage is relatively high. For example, in the first state, the threshold voltage of the self-selecting memory layer 120 may be a first voltage V1, and in the second state, the threshold voltage of the self-selecting memory layer 120 may be a second voltage V2 higher than the first voltage V1.

In a case in which the self-selecting memory layer 120 is in the first state, when a voltage lower than the first voltage V1 is applied to the self-selecting memory layer 120, almost no current flows between both ends of the self-selecting memory layer 120, and when a voltage higher than the first voltage V1 is applied to the self-selecting memory layer 120, the self-selecting memory layer 120 is turned on so that current flows through the self-selecting memory layer 120. Furthermore, in a case in which the self-selecting memory layer 120 is in the second state, when a voltage lower than the second voltage V2 is applied to the self-selecting memory layer 120, almost no current flows between both ends of the self-selecting memory layer 120, and when a voltage higher than the second voltage V2 is applied to the self-selecting memory layer 120, the self-selecting memory layer 120 is turned on so that current flows through the self-selecting memory layer 120. Also, when the self-selecting memory layer 120 is in the second state and a voltage higher than the second voltage V2 is applied to the self-selecting memory layer 120, the self-selecting memory layer 120 may be converted into the first state so that current flows through the self-selecting memory layer 120 while the self-selecting memory layer 120 is in the first state.

Accordingly, a voltage between the first voltage V1 and the second voltage V2 may be selected as a read voltage VR. In a case in which the self-selecting memory layer 120 is in the first state, when the read voltage VR is applied to the self-selecting memory layer 120, current flows through the self-selecting memory layer 120, and in this state, a data value stored in the self-selecting memory layer 120 may be defined as “1.” In a case in which the self-selecting memory layer 120 is in the second state, when the read voltage VR is applied to the self-selecting memory layer 120, almost no current flows through the self-selecting memory layer 120, and in this state, the data value stored in the self-selecting memory layer 120 may be defined as “0.” In other words, when the current flowing in the self-selecting memory layer 120 is measuring while the read voltage VR is applied to the self-selecting memory layer 120, the data value stored in the self-selecting memory layer 120 may be read out.

Meanwhile, in a case in which the self-selecting memory layer 120 is in the first state, when a negative (−) bias voltage is applied to the self-selecting memory layer 120, the threshold voltage of the self-selecting memory layer 120 is increased so that the self-selecting memory layer 120 may be converted into the second state. For example, when a negative third voltage V3 is applied to the self-selecting memory layer 120, the self-selecting memory layer 120 may be converted into the second state. Such an operation may be referred to as a ‘reset (RESET)’ operation. Furthermore, in a case in which the self-selecting memory layer 120 is in the second state, when a positive (+) bias voltage greater than the second voltage V2 is applied to the self-selecting memory layer 120, the threshold voltage of the self-selecting memory layer 120 is decreased so that the self-selecting memory layer 120 may be converted into the first state. Such an operation may be referred to as a ‘set (SET)’ operation. A difference between the second voltage V2 that is a reset (RESET) threshold voltage and the first voltage V1 that is a set (SET) threshold voltage corresponds to a memory window.

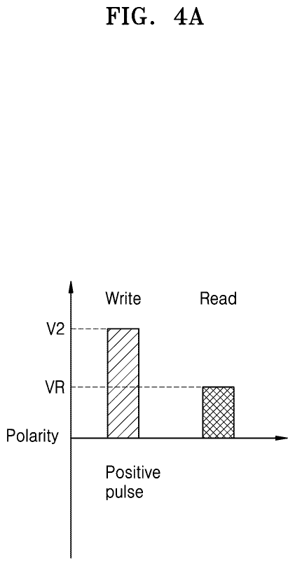

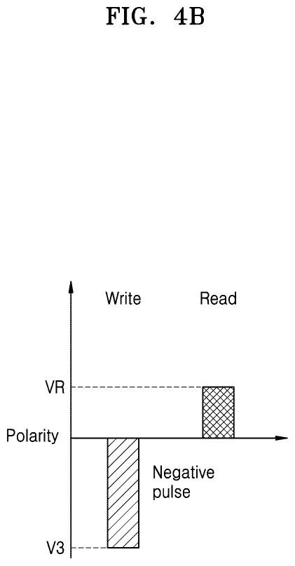

FIG. 4A is a graph showing an example of a bias voltage for a set (SET) operation and a read operation applied to the self-selecting memory layer 120 illustrated in FIG. 2.

Referring to FIG. 4A, in a set (SET) operation, a positive (+) bias voltage greater than or equal to the second voltage V2 may be applied to the self-selecting memory layer 120. Then, the threshold voltage of the self-selecting memory layer 120 may be shifted to the first voltage V1. Thereafter, in a read operation, the positive (+) read voltage VR between the first voltage V1 and the second voltage V2 may be applied to the self-selecting memory layer 120. When the read voltage VR is applied to the self-selecting memory layer 120, the self-selecting memory layer 120 may be turned on.

FIG. 4B is a graph showing an example of a bias voltage for a reset (RESET) operation and a read operation applied to the self-selecting memory layer 120 illustrated in FIG. 2.

Referring to FIG. 4B, in a reset (RESET) operation, a negative (−) bias voltage, that is, the negative third voltage V3 may be applied to the self-selecting memory layer 120. The absolute value of the negative third voltage V3 may be approximately equal to or slightly greater to less than the second voltage V2. Then, the threshold voltage of the self-selecting memory layer 120 may be shifted to the second voltage V2 that is greater than the first voltage V1. Thereafter, in the read operation, the positive (+) read voltage VR between the first voltage V1 and the second voltage V2 may be applied to the self-selecting memory layer 120. When the read voltage VR is applied to the self-selecting memory layer 120, the self-selecting memory layer 120 may not be turned on.

As described above, the self-selecting memory layer 120 may have the Ovonic threshold switching characteristics and simultaneously have memory properties of changing the threshold voltage. In particular, the threshold voltage of the self-selecting memory layer 120 may be shifted according to the polarity of a bias voltage applied to the self-selecting memory layer 120.

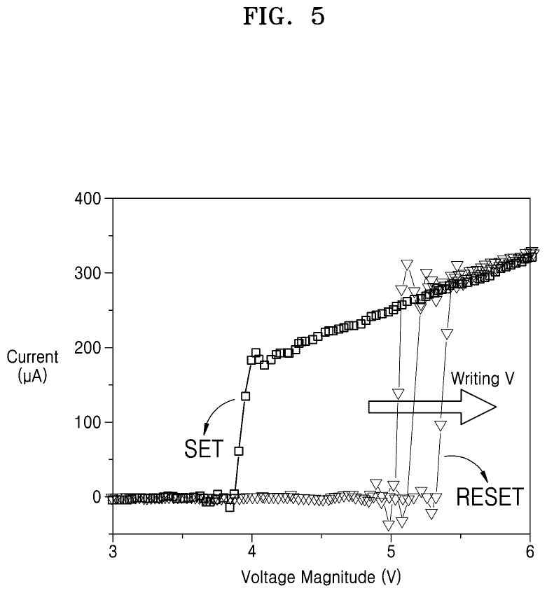

FIG. 5 is a graph showing an example of the voltage-current characteristics according to the magnitude (intensity) of a writing voltage applied to the self-selecting memory layer 120 illustrated in FIG. 2.

Referring to FIG. 5, when a writing voltage applied to the self-selecting memory layer 120 is, for example, a pulse voltage with a positive (+) polarity, even when the magnitude (intensity) of a voltage increases, the set (SET) threshold voltage does not change. In contrast, when the writing voltage applied to the self-selecting memory layer 120 is a pulse voltage, for example, a pulse voltage with a negative (−) polarity, having a different polarity from the set pulse voltage, it may be seen that, as the magnitude (intensity) of a voltage increases, a reset (RESET) threshold voltage increases. Accordingly, by changing the magnitude of a pulse voltage with a negative (−) polarity, the self-selecting memory layer 120 may implement a multi-level memory.

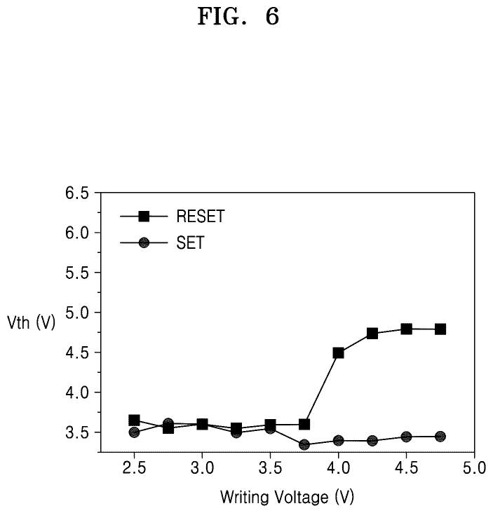

Referring back to FIG. 2, the one end portion of the self-selecting memory layer 120 may be electrically connected to the channel layer 111 of the transistor, and the other end portion of the self-selecting memory layer 120 may be electrically connected to a metal layer 130. The metal layer 130 may apply a voltage to the self-selecting memory layer 120 with the bit lines BL1 and BL2. The metal layer 130 may include, for example, metal, conductive metal nitride, conductive metal oxide, or a combination thereof. However, the disclosure is not limited thereto. The metal layer 130 may be electrically connected to a plurality of write lines AL1, AL2, and AL3 of FIG. 6 described below.

First and second interlayers 141 and 142 may be further provided in both ends of the self-selecting memory layer 120. The first interlayer 141 may be provided between the channel layer 111 of the transistor and the self-selecting memory layer 120, and the second interlayer 142 may be provided between the self-selecting memory layer 120 and the metal layer 130. The first and second interlayers 141 and 142, which function as diffusion barriers, may include, for example, a carbon-based conductive material (e.g., carbon nitride, etc.), but the disclosure is not limited thereto.

FIG. 6 is a graph showing changes in a reset threshold voltage RESET Vth and a set threshold voltage SET Vth according to a writing voltage applied to the self-selecting memory layer 120 illustrated in FIG. 2. In FIG. 6, a writing voltage of (+) polarity was used for measuring a set threshold voltage, and a writing voltage of (−) polarity was used for measuring a reset threshold voltage. Referring to FIG. 6, it may be seen that, as a writing voltage of (−) polarity applied to the self-selecting memory layer 120 increases, the reset threshold voltage RESET Vth gradually increases and then reaches a saturation state. Meanwhile, it may be seen that, even when a writing voltage of (+) polarity applied to the self-selecting memory layer 120 increases, the set threshold voltage SET Vth remains constant.

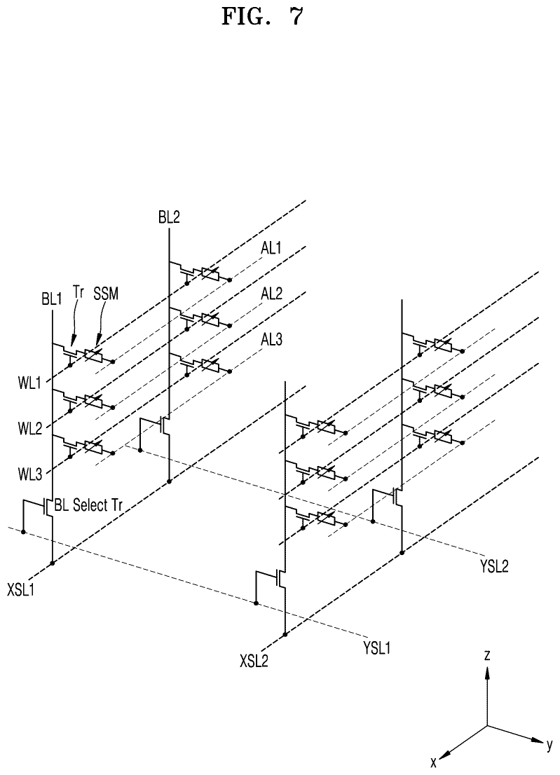

FIG. 7 is a schematic view illustrating an example of a circuit diagram of the 3D memory device 100 according to an embodiment illustrated in FIG. 1.

Referring to FIG. 7, the bit lines BL1 and BL2 may be arranged in the substrate 101 of FIG. 1 in the form of a 2D matrix. Each of the bit lines BL1 and BL2 extends in the direction perpendicular to the substrate 101, for example, the z-axis direction. A plurality of memory cells (the memory cells MC of FIG. 1) are connected to each of the bit lines BL1 and BL2. Accordingly, the memory cells MC are arranged along each of the bit lines BL1 and BL2 in the direction perpendicular to the substrate 101, for example, the z-axis direction.

As described above, each of the memory cells MC may include a transistor Tr and a self-selecting memory layer SSM connected in series to the transistor Tr. In the circuit diagram illustrated in FIG. 6, “Tr” denotes a transistor including the channel layer 111, the gate electrode 115, and the gate insulating layer 113, which are illustrated in FIG. 2, and “SSM” denotes the self-selecting memory layer 120 having the characteristics of performing a memory function and a selector function, which is illustrated in FIG. 2.

The channel layer 111 in the transistor Tr may extend in the direction parallel to the substrate 101, for example, the y-axis direction. One end portion of the channel layer 111 is electrically connected to a corresponding one of the bit lines BL1 and BL2, and the other end portion of the channel layer 111 is electrically connected to the self-selecting memory layer SSM. The metal layer 130 of FIG. 2 is connected to one end portion of the self-selecting memory layer SSM, and the metal layer 130 may be connected to the write lines AL1, AL2, and AL3. The write lines AL1, AL2, and AL3 may extend in the direction parallel to the substrate 101, for example, the x-axis direction.

The word lines WL1, WL2, and WL3 may intersect the bit lines BL1 and BL2. The word lines WL1, WL2, and WL3 may each extend in the direction parallel to the substrate 101, for example, the x-axis direction. The word lines WL1, WL2, and WL3 may each be connected in common to, for example, the gate electrodes 115 of the transistors Tr arranged in the x-axis direction. A voltage to turn on/off the channel layer 111 may be selectively applied to the gate electrode 115 through the word lines WL1 and WL2. The gate electrode 115 may be integrally formed with the word lines WL1, WL2, and WL3.

A plurality of select lines XSL1, XSL2, YSL1, and YSL2 performing a function to select a desired one of the bit lines BL1 and BL2 may be disposed under the bit lines BL1 and BL2. These select lines XSL1, XSL2, YSL1, and YSL2 may be formed on the upper surface of the substrate 101. The select lines XSL1, XSL2, YSL1, and YSL2 may include the X select lines XSL1 and XSL2 and the Y select lines YSL1 and YSL2 which intersect each other. The X select lines XSL1 and XSL2 may each extend in a first direction, for example, the x-axis direction, and the Y select lines YSL1 and YSL2 may each extend in a second direction, for example, the y-axis direction.

A bit line select transistor BL Select Tr to select a desired and/or alternatively predetermined one of the bit lines BL1 and BL2 may be arranged at each of intersections where the X select lines XSL1 and XSL2 intersect the Y select lines YSL1 and YSL2. The X select lines XSL1 and XSL2 and the bit lines BL1 and BL2 may be respectively connected to a source and a drain of the bit line select transistor BL Select Tr, and each of the Y select lines YSL1 and YSL2 may be connected to a gate of the bit line select transistor BL Select Tr.

In the circuit diagram of the 3D memory device 100 illustrated in FIG. 7, a desired one of the bit lines BL1 and BL2 may be selected by applying a signal to each of a desired and/or alternatively predetermined one of the X select lines XSL1 and XSL2 and a desired and/or alternatively predetermined one of the Y select lines YSL1 and YSL2 to drive a desired and/or alternatively predetermined bit line select transistor BL Select Tr. The memory cell MC for a write or read operation may be selected by applying a voltage to a desired and/or alternatively predetermined one of the word lines WL1, WL2, and WL3 intersecting the selected one of the bit lines BL1 and BL2. In order for the channel layer 111 of the selected memory cell MC to be in a channel on-state, a certain voltage may be applied to the gate electrode 115 through one of the word lines WL1, WL2, and WL3.

When a write operation is performed on the selected memory cell MC, a set operation or reset operation may be performed on the selected memory cell MC by applying a voltage greater than or equal to the threshold voltage of the self-selecting memory layer SSM to the transistor Tr through one of the bit lines BL1 and BL2. As described above, when the voltage applied to the self-selecting memory layer SSM is a pulse voltage having a different polarity from that of a set pulse voltage, for example, a pulse voltage with a negative (−) polarity, as the magnitude (intensity) of a voltage increases, the reset threshold voltage RESET Vth may increase. Accordingly, by changing the magnitude of a pulse voltage with a negative (−) polarity applied to the self-selecting memory layer SSM, the self-selecting memory layer SSM may implement a multi-level memory.

When a read operation is performed on the selected memory cell MC, a read operation may be performed on the selected memory cell MC by applying a voltage less than or equal to the threshold voltage of the self-selecting memory layer SSM to the transistor TR through one of the bit lines BL1 and BL2. As a voltage less than or equal to the threshold voltage of the self-selecting memory layer SSM may be used as the read voltage, a non-destructive read operation may be performed.

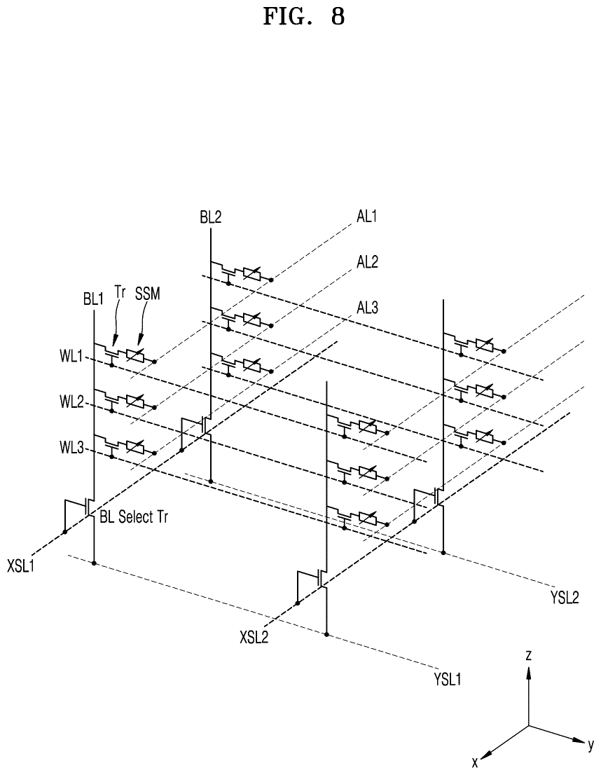

FIG. 8 is a schematic view illustrating another example of a circuit diagram of the 3D memory device 100 according to an embodiment illustrated in FIG. 1. In the following description, differences from the circuit diagram illustrated in FIG. 7 are mainly described.

Referring to FIG. 8, the bit lines BL1 and BL2 each extend in the direction perpendicular to the substrate 101 on the substrate 101, and the memory cells MC are arranged along each of the bit lines BL1 and BL2 in the direction perpendicular to the substrate 101.

Each of the memory cells MC may include the transistor Tr and the self-selecting memory layer SSM connected in series to the transistor Tr. The channel layer 111 in the transistor Tr may extend in the direction parallel to the substrate 101. One end portion of the channel layer 111 is electrically connected to a corresponding one of the bit lines BL1 and BL2, and the other end portion of the channel layer 111 may be electrically connected to the self-selecting memory layer SSM. The metal layer 130 of FIG. 2 is connected to one end portion of the self-selecting memory layer SSM, and the metal layer 130 may be connected to the write lines AL1, AL2, and AL3.

The word lines WL1, WL2, and WL3 intersect the bit lines BL1 and BL2. The word lines WL1, WL2, and WL3 may be respectively connected in common to, for example, the gate electrodes 115 of the transistors Tr arranged in the x-axis direction. The select lines XSL1, XSL2, YSL1, and YSL2 performing a function to select a desired one of the bit lines BL1 and BL2 may be disposed under the bit lines BL1 and BL2.

The select lines XSL1, XSL2, YSL1, and YSL2 may include the X select lines XSL1 and XSL2 and the Y select lines YSL1 and YSL2 intersecting each other. The X select lines XSL1 and XSL2 may each extend in the first direction, for example, the x-axis direction, and the Y select lines YSL1 and YSL2 may each extend in the second direction, for example, the y-axis direction.

The bit line select transistor BL Select Tr to select a desired and/or alternatively predetermined one of the bit lines BL1 and BL2 may be arranged at each of intersections where the X select lines XSL1 and XSL2 intersect the Y select lines YSL1 and YSL2. The Y select lines YSL1 and YSL2 and the bit lines BL1 and BL2 may be respectively connected to a source and a drain of the bit line select transistor BL Select Tr, and each of the X select lines XSL1 and XSL2 may be connected to a gate of the bit line select transistor BL Select Tr.

In the circuit diagram of the 3D memory device 100 illustrated in FIG. 8, desired one of the bit lines BL1 and BL2 may be selected by applying a signal to each of a desired and/or alternatively predetermined one of the X select lines XSL1 and XSL2 and a desired and/or alternatively predetermined one of the Y select lines YSL1 and YSL2 to drive a desired and/or alternatively predetermined bit line select transistor BL Select Tr. The memory cell MC for a write or read operation may be selected by applying a voltage to a desired and/or alternatively predetermined one of the word lines WL1, WL2, and WL3 intersecting the selected one of the bit lines BL1 and BL2.

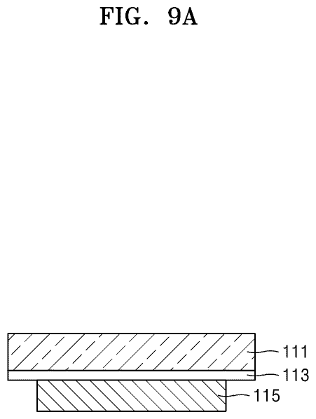

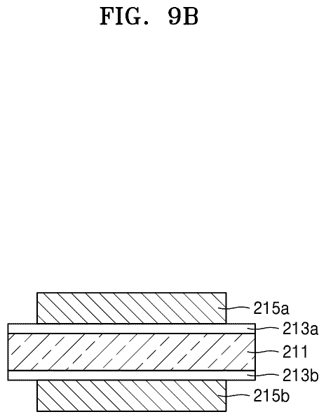

FIGS. 9A and 9B illustrate example structures of a transistor applicable to the memory cell MC of the 3D memory device 100 according to an embodiment.

FIG. 9A illustrates a case in which, as illustrated in FIG. 2, a transistor includes one channel layer 111 and one gate electrode 115. Referring to FIG. 9A, the transistor includes the channel layer 111 and the gate electrode 115 provided under the channel layer 111. The gate insulating layer 113 is provided between the channel layer 111 and the gate electrode 115. Although FIG. 9A illustrates an example in which the gate electrode 115 is provided under the channel layer 111, the gate electrode 115 may be provided above the channel layer 111.

FIG. 9B illustrates a case in which a transistor includes one channel layer 211 and two gate electrodes 215a and 215b. Referring to FIG. 9B, the transistor includes the channel layer 211, the first gate electrode 215a provided above the channel layer 211, and the second gate electrode 215b provided under the channel layer 211. A first gate insulating layer 213A is provided between the channel layer 211 and the first gate electrode 215a, and a second gate insulating layer 213B is provided between the channel layer 211 and the second gate electrode 215b.

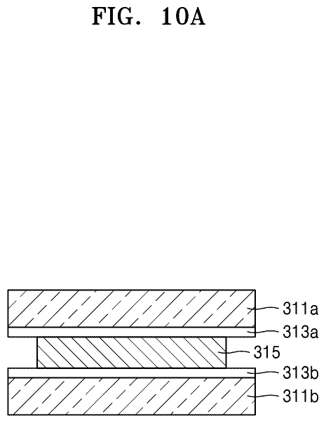

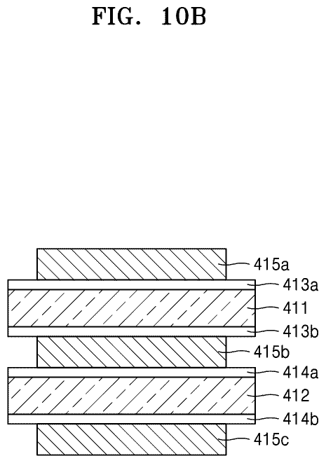

FIGS. 10A and 10B illustrate other example structures of a transistor applicable to the memory cell MC of the 3D memory device 100 according to an embodiment.

FIG. 10A illustrates a case in which a transistor includes one gate electrode 315 and two channel layers 311a and 311b. Referring to FIG. 10A, the transistor includes the gate electrode 315, the first channel layer 311a provide above the gate electrode 315, and the second channel layer 311b provided under the gate electrode 315. A first gate insulating layer 313A is provided between the gate electrode 315 and the first channel layer 311a, and a second gate insulating layer 313B is provided between the gate electrode 315 and the second channel layer 311b.

FIG. 10B illustrates a case in which a transistor includes two channel layers 411 and 412 and three gate electrodes 415a, 415b, and 415c. Referring to FIG. 10B, the transistor includes the first and second channel layers 411 and 412 arranged apart from each other, the first gate electrode 415a provided above the first channel layer 411, the second gate electrode 415b provided between the first and second channel layers 411 and 412, and the third gate electrode 415c provided under the second channel layer 412. First and second gate insulating layers 413A and 413B are provided on the upper surface and the lower surface of the first channel layer 411, respectively, and third and fourth gate insulating layers 414a and 414b are provided on the upper surface and the lower surface of the second channel layer 412, respectively. The structures of the transistors illustrated in FIGS. 9A and 9B, and FIGS. 10A and 10B described above are just examples, and the transistor may have various other structures.

As described above, in the 3D memory device 100 according to an embodiment, each of the memory cells MC has a structure in which the transistor Tr and the self-selecting memory layer SSM capable of performing both of a memory function and a selector function are connected to each other in series. In other words, each of the memory cells MC has a structure in which two switching elements are connected to each other in series, and thus, a leakage current may be controlled in two ways. For example, even when the transistor is in an on-state, the memory cell MC may maintain an off-state at a voltage that is less than or equal to a certain voltage (e.g., about 1 V). Accordingly, the 3D memory device 100 with reduced leakage current and standby power may be implemented.

The 3D memory device 100 according to an embodiment having the self-selecting memory layer SSM having trap-based memory properties is capable of sub-nanosecond switching, and thus, very fast high-speed memory properties may be implemented.

In the 3D memory device 100 according to an embodiment, in order to perform a read operation on the memory cells MC, a voltage less than or equal to the threshold voltage of the self-selecting memory layer SSM is used as a read voltage, and thus, a non-destructive read operation is possible. Furthermore, as memory refresh that is essentially required in DRAM is not necessary in the 3D memory device 100 according to an embodiment, operation may be simplified and consumption power may be improved.

In the 3D memory device 100 according to an embodiment, by changing the magnitude of a reset pulse voltage applied to the self-selecting memory layer SSM, multi-level memory properties may be implemented, and the memory window may be easily adjusted.

Although, in a 3D memory device having a cross point array structure which does not use a transistor, an IR drop problem may occur due to long lengths of bit lines and word lines, in the 3D memory device 100 according to an embodiment, each of the memory cells MC includes the transistor Tr connected in series to the self-selecting memory layer SSM so that the IR drop problem may be reduced. Furthermore, in the 3D memory device 100 according to an embodiment, as an operation current of the self-selecting memory layer SSM can be controlled by adjusting a gate voltage applied to the transistor Tr, a write power may be reduced.

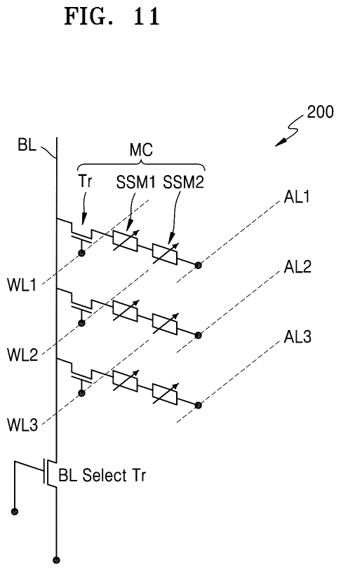

FIG. 11 is a schematic circuit diagram of a 3D memory device 200 according to another embodiment. Although the 3D memory device 200 according to the present embodiment includes a plurality of bit lines as illustrated in FIGS. 7 and 8, for convenience, FIG. 11 illustrates only one bit line BL.

Referring to FIG. 11, the 3D memory device 200 may include a plurality of memory cells MC arranged in three dimensions on a substrate (not shown). A plurality of bit lines BL are provided on the substrate to extend in a direction perpendicular to the substrate, and the memory cells MC are arranged along the bit lines BL in the direction perpendicular to the substrate. In this state, the memory cells MC may each extend in a direction perpendicular to the bit line BL. The word lines WL1, WL2, and WL3 extend in a direction parallel to the substrate to intersect the bit line BL. One end portion of each of the memory cells MC may be electrically connected to a corresponding bit line BL, and the bit line BL may have a function of applying a voltage to each of the memory cells MC. The other end portion of each of the memory cells MC may be connected to the write lines AL1, AL2, and AL3.

Each of the memory cells MC provided between the bit line BL and the write lines AL1, AL2, and AL3 may include the transistor Tr and first and second self-selecting memory layers SSM1 and SSM2 electrically connected to the transistor Tr. In this state, the first and second self-selecting memory layers SSM1 and SSM2 are connected in series to the transistor Tr.

The transistor Tr may include a channel layer, a gate electrode, and a gate insulating layer. As the transistor Tr is described in detail in the embodiment described above, a description thereof is omitted. While the channel layer of the transistor Tr may extend parallel to the substrate, one end portion of the channel layer may be electrically connected to the bit line BL, and the other end portion of the channel layer may be electrically connected to the first and second self-selecting memory layers SSM1 and SSM2.

The first and second self-selecting memory layers SSM1 and SSM2 are connected in series to the transistor Tr. As described above, the first and second self-selecting memory layers SSM1 and SSM2 may each have a high resistance state when a voltage lower than a threshold voltage is applied thereto, and may each have Ovonic threshold switching properties having a low resistance state when a voltage higher than the threshold voltage is applied thereto. Furthermore, the first and second self-selecting memory layers SSM1 and SSM2 may each have memory properties of the threshold voltage being shifted depending on the polarity and intensity of the applied bias voltage. Accordingly, the first and second self-selecting memory layers SSM1 and SSM2 may each have properties of performing both of a memory function and a selector function. As each of the first and second self-selecting memory layers SSM1 and SSM2 is described in detail in the embodiment described above, a description thereof is omitted.

The first and second self-selecting memory layers SSM1 and SSM2 may have different threshold voltages from each other. In detail, the first and second self-selecting memory layers SSM1 and SSM2 may have different reset threshold voltages from each other. For example, the first self-selecting memory layer SSM1 may have a first reset threshold voltage Vth1r, and the second self-selecting memory layer SSM2 may have a the second reset threshold voltage Vth2r higher than the first reset threshold voltage. As such, the memory cells MC each include the first and second self-selecting memory layers SSM1 and SSM2 connected in series to the transistor Tr and having different threshold voltages, and thus, the multilevel memory as described below may be implemented.

In the following description, a method of implementing a multilevel memory by using the first and second self-selecting memory layers SSM1 and SSM2 connected to each other in series is described.

The resistances of the first and second self-selecting memory layers SSM1 and SSM2 are R1set and R2set, respectively, in an initial SET state, and R1set and R2set are assumed to be the same value. In this case, when the voltage applied to both ends of the first and second self-selecting memory layers SSM1 and SSM2 is Vdd, the voltage applied to each of the first and second self-selecting memory layers SSM1 and SSM2 connected to each other in series may be Vdd/2.

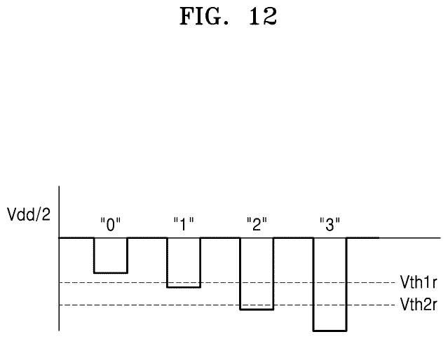

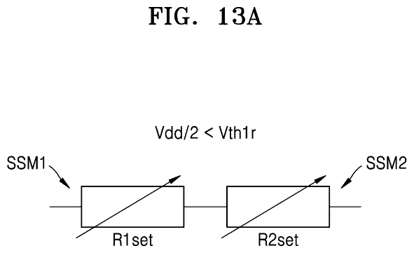

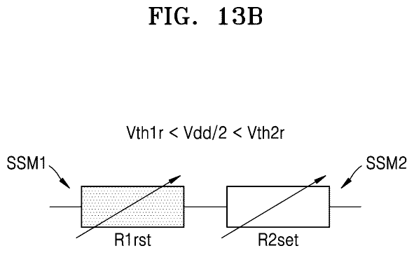

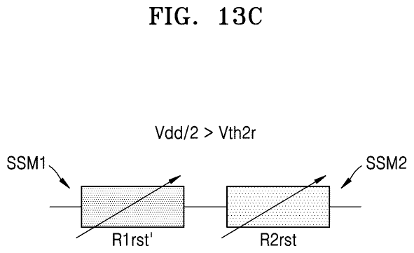

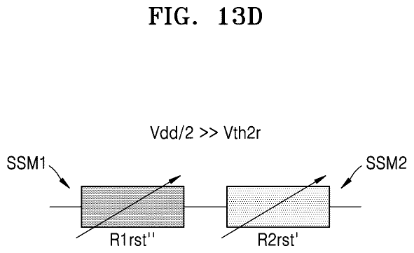

FIG. 12 illustrates a voltage Vdd/2 applied to each of the first and second self-selecting memory layers SSM1 and SSM2 illustrated in FIG. 11, in four states (“0”, “1”, “2”, and “3”). FIGS. 13A to 13D illustrate the resistance of each of the first and second self-selecting memory layers SSM1 and SSM2 in the four states (“0”, “1”, “2”, and “3”) illustrated in FIG. 12.

Referring to FIGS. 12 and 13A, in the “0” state, the voltage Vdd/2 lower than the first reset threshold voltage Vth1r is applied to each of the first and second self-selecting memory layers SSM1 and SSM2. In this case, the first and second self-selecting memory layers SSM1 and SSM2 may both have a low resistance state. Accordingly, the resistance of the first self-selecting memory layer SSM1 may be R1set, and the resistance of the second self-selecting memory layer SSM2 may be R2set. In the “0” state, when the sum of the resistance of the first self-selecting memory layer SSM1 and the resistance of the second self-selecting memory layer SSM2 is represented as “R0,” it may be that R0=R1set+R2set.

Referring to FIGS. 12 and 13B, in the “1” state, the voltage Vdd/2 that is higher than the first reset threshold voltage Vth1r and lower than the second reset threshold voltage Vth2r is applied to each of the first and second self-selecting memory layers SSM1 and SSM2. In this case, the first self-selecting memory layer SSM1 may have a high resistance state, and the second self-selecting memory layer SSM2 may have a low resistance state. Accordingly, the resistance of the first self-selecting memory layer SSM1 may be R1rst (>R1set), and the resistance of the second self-selecting memory layer SSM2 may be R2set. In the “1” state, when the sum of the resistance of the first self-selecting memory layer SSM1 and the resistance of the second self-selecting memory layer SSM2 is represented as R1 (>R0), it may be that R1=R1rst+R2set.

Referring to FIGS. 12 and 13C, in the “2” state, the voltage Vdd/2 higher than the second reset threshold voltage Vth2r is applied to each of the first and second self-selecting memory layers SSM1 and SSM2. In this case, the first self-selecting memory layer SSM1 may have a higher resistance state than that in FIG. 13B, and the second self-selecting memory layer SSM2 may have a high resistance state. Accordingly, the resistance of the first self-selecting memory layer SSM1 may be R1rst′ (>R1rst), and the resistance of the second self-selecting memory layer SSM2 may be R2rst (>R2set). In the “2” state, when the sum of the resistance of the first self-selecting memory layer SSM1 and the resistance of the second self-selecting memory layer SSM2 is represented as R2 (>R1), it may be that R2=R1rst′+R2rst.

Referring to FIGS. 12 and 13D, in the “3” state, the voltage Vdd/2 quite higher than the second reset threshold voltage Vth2r is applied to each of the first and second self-selecting memory layers SSM1 and SSM2. In this case, the first self-selecting memory layer SSM1 may have a high resistance state that is quite higher than that in FIG. 13C, and the second self-selecting memory layer SSM2 may have a higher resistance state than that in FIG. 13C. Accordingly, the resistance of the first self-selecting memory layer SSM1 may be R1rst″ (>R1rst′), and the resistance of the second self-selecting memory layer SSM2 may be R2rst′ (>R2rst). In the “3” state, when the sum of the resistance of the first self-selecting memory layer SSM1 and the resistance of the second self-selecting memory layer SSM2 is represented as R3 (>R2), it may be that R3=R1rst″+R2rst′.

As described above, when the memory cells MC include the first and second self-selecting memory layers SSM1 and SSM2 connected to each other in series and having different threshold voltages (in detail, reset threshold voltages), four multi-resistance states may be implemented by changing the voltage applied to each of the first and second self-selecting memory layers SSM1 and SSM2. Although a case in which the memory cells MC include two self-selecting memory layers SSM1 and SSM2 connected to each other in series are described above, the disclosure is not limited thereto, and it is possible that the memory cells MC include three or more self-selecting memory layers connected to each other in series and having different threshold voltages.

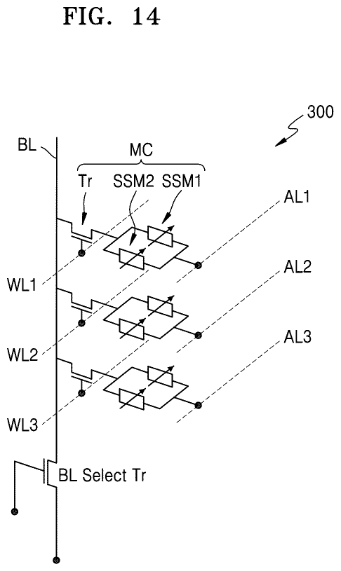

FIG. 14 is a schematic circuit diagram of a 3D memory device 300 according to another embodiment. Although the 3D memory device 300 according to the present embodiment includes a plurality of bit lines illustrated in FIGS. 7 and 8, for convenience, FIG. 14 illustrates only one bit line BL.

Referring to FIG. 14, the 3D memory device 300 includes a plurality of memory cells MC arranged in three dimensions on a substrate (not shown). A plurality of bit lines BL are provided on the substrate to extend in a direction perpendicular to the substrate, and the memory cells MC are arranged along the bit lines BL in the direction perpendicular to the substrate. In this state, the memory cells MC may each extend in a direction perpendicular to the bit line BL. The word lines WL1, WL2, and WL3 extend in a direction parallel to the substrate to intersect the bit lines BL. One end portion of each of the memory cells MC may be electrically connected to a corresponding bit line BL, and the bit line BL may have a function of applying a voltage to each of the memory cells MC. The other end portion of each of the memory cells MC may be connected to the write lines AL1, AL2, and AL3.

Each of the memory cells MC provided between the bit line BL and the write lines AL1, AL2, and AL3 may include the transistor Tr and first and second self-selecting memory layers SSM1 and SSM2 electrically connected to the transistor Tr. In this state, the first and second self-selecting memory layers SSM1 and SSM2 are connected in parallel to the transistor Tr.

The transistor Tr may include a channel layer, a gate electrode, and a gate insulating layer. As the transistor Tr is described in detail in the embodiment described above, a description thereof is omitted. While the channel layer of the transistor Tr may extend parallel to the substrate, one end portion of the channel layer may be electrically connected to the bit line BL, and the other end portion of the channel layer may be electrically connected to the first and second self-selecting memory layers SSM1 and SSM2.

The first and second self-selecting memory layers SSM1 and SSM2 are connected in parallel to the transistor Tr. As described above, the first and second self-selecting memory layers SSM1 and SSM2 may each have a high resistance state when a voltage lower than a threshold voltage is applied thereto, and may each have Ovonic threshold switching properties having a low resistance state when a voltage higher than the threshold voltage is applied thereto. Furthermore, the first and second self-selecting memory layers SSM1 and SSM2 may each have memory properties of the threshold voltage being shifted depending on the polarity and intensity of the applied bias voltage. Accordingly, the first and second self-selecting memory layers SSM1 and SSM2 may each have properties of performing both of a memory function and a selector function. As each of the first and second self-selecting memory layers SSM1 and SSM2 is described in detail in the embodiment described above, a description thereof is omitted.

The first and second self-selecting memory layers SSM1 and SSM2 may have different threshold voltages from each other. In detail, the first and second self-selecting memory layers SSM1 and SSM2 may have different reset threshold voltages from each other. For example, the first self-selecting memory layer SSM1 may have the first reset threshold voltage Vth1r, and the second self-selecting memory layer SSM2 may have a the second reset threshold voltage Vth2r higher than the first reset threshold voltage. As such, the memory cells MC each include the first and second self-selecting memory layers SSM1 and SSM2 connected in parallel to the transistor Tr and having different threshold voltages, and thus, the multilevel memory as described below may be implemented.

In the following description, a method of implementing a multilevel memory by using the first and second self-selecting memory layers SSM1 and SSM2 connected to each other in parallel is described.

The resistances of the first and second self-selecting memory layers SSM1 and SSM2 are R1set and R2set, respectively, in an initial SET state, and R1set and R2set are assumed to be the same value. In this case, when the voltage applied to both ends of the first and second self-selecting memory layers SSM1 and SSM2 is Vdd, the voltage applied to each of the first and second self-selecting memory layers SSM1 and SSM2 connected to each other in parallel may be Vdd.

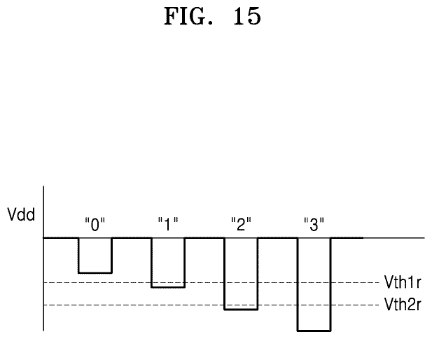

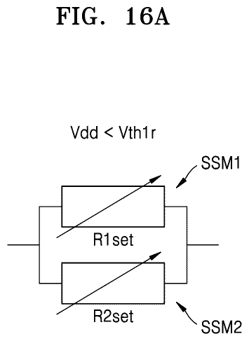

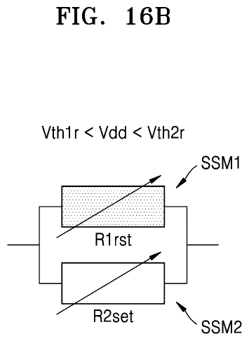

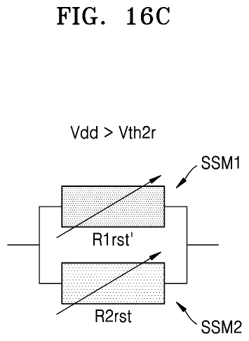

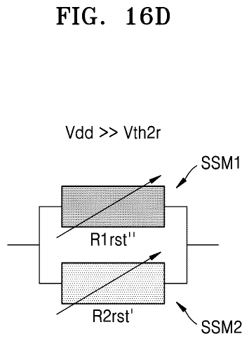

FIG. 15 illustrates a voltage Vdd applied to each of the first and second self-selecting memory layers SSM1 and SSM2 illustrated in FIG. 14, in four states (“0”, “1”, “2”, and “3”). FIGS. 16A to 16D illustrate the resistance of each of the first and second self-selecting memory layers SSM1 and SSM2 in the four states (“0”, “1”, “2”, and “3”) illustrated in FIG. 15.

Referring to FIGS. 15 and 16A, in the “0” state, the voltage Vdd lower than the first reset threshold voltage Vth1r is applied to each of the first and second self-selecting memory layers SSM1 and SSM2. In this case, the first and second self-selecting memory layers SSM1 and SSM2 may both have a low resistance state. Accordingly, the resistance of the first self-selecting memory layer SSM1 may be R1set, and the resistance of the second self-selecting memory layer SSM2 may be R2set. In the “0” state, the sum of the resistance of the first self-selecting memory layer SSM1 and the resistance of the second self-selecting memory layer SSM2 is represented as “R0”, it may be that 1/R0=1/R1set+1/R2set.

Referring to FIGS. 15 and 16B, in the “1” state, the voltage Vdd that is higher than the first reset threshold voltage Vth1r and lower than the second reset threshold voltage Vth2r is applied to each of the first and second self-selecting memory layers SSM1 and SSM2. In this case, the first self-selecting memory layer SSM1 may have a high resistance state, and the second self-selecting memory layer SSM2 may have a low resistance state. Accordingly, the resistance of the first self-selecting memory layer SSM1 may be R1rst (>R1set), and the resistance of the second self-selecting memory layer SSM2 may be R2set. In the “1” state, when the sum of the resistance of the first self-selecting memory layer SSM1 and the resistance of the second self-selecting memory layer SSM2 is represented as R1 (>R0), it may be that 1/R1=1/R1rst+1/R2set.

Referring to FIGS. 15 and 16C, in the “2” state, the voltage Vdd higher than the second reset threshold voltage Vth2r is applied to each of the first and second self-selecting memory layers SSM1 and SSM2. In this case, the first self-selecting memory layer SSM1 may have a higher resistance state than that in FIG. 16B, and the second self-selecting memory layer SSM2 may have a high resistance state. Accordingly, the resistance of the first self-selecting memory layer SSM1 may be R1rst′ (>R1rst), and the resistance of the second self-selecting memory layer SSM2 may be R2rst (>R2set). In the “2” state, when the sum of the resistance of the first self-selecting memory layer SSM1 and the resistance of the second self-selecting memory layer SSM2 is represented as R2 (>R1), it may be that 1/R2=1/R1rst′+1/R2rst.

Referring to FIGS. 15 and 16D, in the “3” state, the voltage Vdd quite higher than the second reset threshold voltage Vth2r is applied to each of the first and second self-selecting memory layers SSM1 and SSM2. In this case, the first self-selecting memory layer SSM1 may have a high resistance state that is higher than that in FIG. 16C, and the second self-selecting memory layer SSM2 may have a higher resistance state than that in FIG. 16C. Accordingly, the resistance of the first self-selecting memory layer SSM1 may be R1rst′ (>R1rst′), and the resistance of the second self-selecting memory layer SSM2 may be R2rst′ (>R2rst). In the “3” state, when the sum of the resistance of the first self-selecting memory layer SSM1 and the resistance of the second self-selecting memory layer SSM2 is represented as R3 (>R2), it may be that R3=R1rst″+R2rst′.

As described above, when the memory cells MC each include the first and second self-selecting memory layers SSM1 and SSM2 connected to each other in parallel and having different threshold voltages (in detail, reset threshold voltages), four multi-resistance states may be implemented by changing the voltage applied to each of the first and second self-selecting memory layers SSM1 and SSM2. Although a case in which the memory cells MC each include two self-selecting memory layers SSM1 and SSM2 connected to each other in parallel are described above, the disclosure is not limited thereto, and it is possible that the memory cells MC each include three or more self-selecting memory layers connected to each other in parallel and having different threshold voltages.

The 3D memory devices 100, 200, and 300 according to the embodiments described above may be used for storing data in various electronic apparatuses. For example, the 3D memory device 100 may be highly likely to be used in the fields of neuromorphic computing, in-memory computing, AI training & inference which requires large capacity, and may be applied in various other fields.

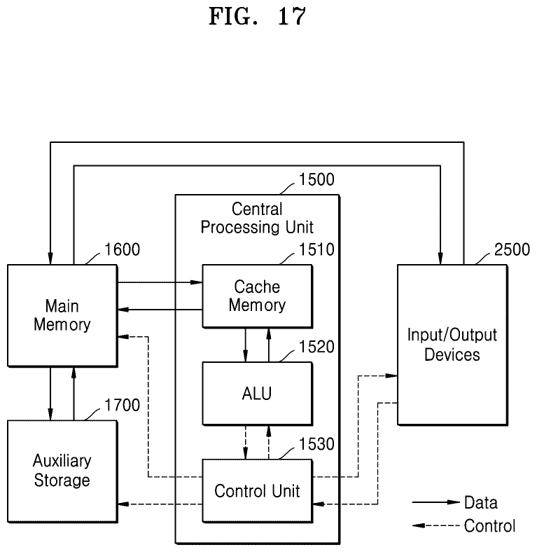

FIG. 17 is a conceptual view schematically showing a device architecture applicable to an exemplary electronic apparatus.

Referring to FIG. 17, a cache memory 1510, an ALU 1520, and a control unit 1530 may constitute a central processing unit (CPU) 1500, and the cache memory 1510 may include a static random access memory (SRAM). Separately from the CPU 1500, a main memory 1600 and an auxiliary storage 1700 may be provided. The main memory 1600 may include a DRAM device, and the auxiliary storage 1700 may include the 3D memory device 100, 200, or 300 described above. In some cases, a device architecture may be implemented in the form of one chip in which computing unit elements and memory unit elements are adjacent to each other, without distinction of sub-units. In some cases, the device architecture may include input/output devices 2500 (e.g., keyboard, mouse).

The 3D memory device 100 according to an embodiment described above, which is implemented as a chip type memory block, may be used as a neuromorphic computing platform or used to constitute a neural network.

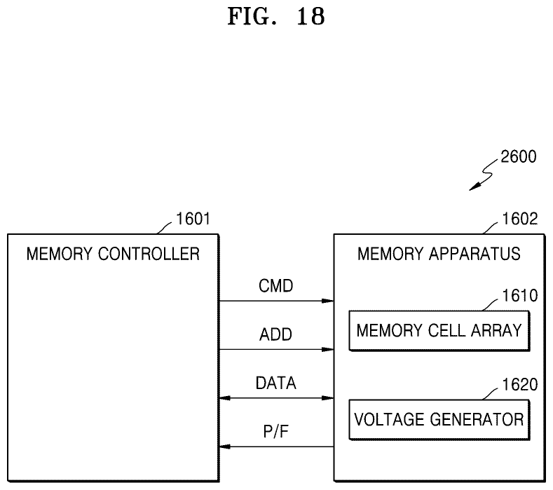

FIG. 18 is a block diagram of a memory system 2600 according to an embodiment.

Referring to FIG. 18, the memory system 2600 may include a memory controller 1601 and a memory apparatus 1602. The memory controller 1601 performs a control operation on the memory apparatus 1602. For example, the memory controller 1601 provides the address ADD to the memory apparatus 1602 and a command CMD to perform programming (or writing), read, and/or erase operations on the memory apparatus 1602 to the memory apparatus 1602. Furthermore, data for a programming operation and a read operation may be transmitted between the memory controller 1601 and the memory apparatus 1602.

The memory apparatus 1602 may include a memory cell array 1610 and a voltage generator 1620. The memory cell array 1610 may include a plurality of memory cells and include the 3D memory device 100, 200, or 300 according to an embodiment described above.

The memory controller 1601 may include a processing circuitry such as hardware including a logic circuit, a hardware/software combination such as a processor that executes software, or a combination thereof. For example, the processing circuitry may include, in detail, a central processing device (CPU), an arithmetic logic unit (ALU), a digital signal processor, a microcomputer, a field programmable gate array (FPGA), a system-on-chip (SoC), a programmable logic unit, a microprocessor, or an application-specific integrated circuit (ASIC), but the disclosure is not limited thereto. The memory controller 1601 may be configured to operate in response to a request from a host (not shown), access the memory apparatus 1602, and control the control operations (e.g., a write/read operation) discussed above, thereby converting the memory controller 1601 into a special purpose controller. The memory controller 1601 may generate an address ADD and the command CMD to perform programming/read/erase operations on the memory cell array 1610. Furthermore, in response to the command CMD from the memory controller 1601, the voltage generator 1620 (e.g., a power circuit) may generate a voltage control signal to control a voltage level of a word line for data programming or data reading with respect to the memory cell array 1610.

Furthermore, the memory controller 1601 may perform a determination operation on the data read from the memory apparatus 1602. For example, the number of on-cells and/or the number of off-cells may be determined from the data read from the memory cells. The memory apparatus 1602 may provide a pass/fail signal P/F to the memory controller 1601 according to a read result of the read data. The memory controller 1601 may control write and read operations on the memory cell array 1610 by referring to the pass/fail signal P/F.

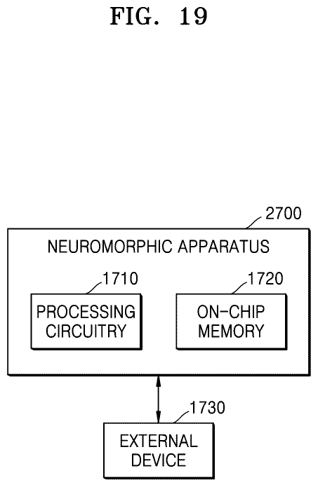

FIG. 19 is a block diagram showing a neuromorphic apparatus 2700 according to an embodiment and an external device connected thereto.

Referring to FIG. 19, the neuromorphic apparatus 2700 may include a processing circuitry 1710 and/or an on-chip memory 1720. The neuromorphic apparatus 2700 may include the 3D memory device 100, 200, or 300 according to an embodiment described above.

In some embodiments, the processing circuitry 1710 may be configured to control a function to drive the neuromorphic apparatus 2700. For example, the processing circuitry 1710 may be configured to control the neuromorphic apparatus 2700 by executing a program stored in the on-chip memory 1720. In some embodiments, the processing circuitry 1710 may include a processing circuitry such as hardware including a logic circuit, a hardware/software combination such as a processor that executes software, or a combination thereof. For example, the processor may include a CPU, a graphics processing device (GPU), an application processor (AP) included in the neuromorphic apparatus 2700, an ALU, a digital signal processor, a microcomputer, an FPGA, an SoC, a programmable logic unit, a microprocessor, or an ASIC, but the disclosure is not limited thereto. In some embodiments, the processing circuitry 1710 may be configured to read/write various pieces of data with respect to an external device 1730 and/or execute the neuromorphic apparatus 2700 using the read/written data. In some embodiments, the external device 1730 may include an external memory having an image sensor (e.g., a CMOS image sensor circuit) and/or a sensor array.

In some embodiments, the neuromorphic apparatus 2700 of FIG. 19 may be applied to a machine learning system. Such machine learning systems may utilize various artificial neural network organizational and processing models, such as convolutional neural networks (CNN), de-convolutional neural networks, recurrent neural networks (RNN) optionally including long short-term memory (LSTM) units and/or gated recurrent units (GRU), stacked neural networks (SNN), state-space dynamic neural networks (SSDNN), deep belief networks (DBN), generative adversarial networks (GANs), and/or restricted Boltzmann machines (RBM).

Alternatively or additionally, such machine learning systems may include other forms of machine learning models, such As, for example, linear and/or logistic regression, statistical clustering, Bayesian classification, decision trees, dimensionality reduction such as principal component analysis, and expert systems; and/or combinations thereof, including ensembles such as random forests. Such machine learning models may be used to provide various services and/or applications, for example, an image classify service, a user authentication service based on bio-information or biometric data, an advanced driver assistance system (ADAS) service, a voice assistant service, an automatic speech recognition (ASR) service, or the like, and may be executed by other electronic devices.

As described above, in the 3D memory device according to an embodiment, as each memory cell has a structure in which a plurality of switching devices (i.e., a transistor and a plurality of self-selecting memory layers) are connected to each other, a leakage current may be double-controlled so that a 3D memory device capable of reducing leakage current and standby power may be implemented. Furthermore, each memory cell includes a plurality of self-selecting memory layers having different threshold voltages, and thus, a multilevel memory may be easily implemented.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that described above 3D memory device described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A three-dimensional (3D) memory device comprising:
a plurality of memory cells arranged in three dimensions on a substrate, wherein
each of the plurality of memory cells comprises a transistor and a plurality of self-selecting memory layers connected to the transistor,
the transistor includes at least one channel layer parallel to the substrate,
each of the plurality of self-selecting memory layers includes a chalcogenide-based material having Ovonic threshold switching characteristics,
a threshold voltage of the chalcogenide-based material changes according to a polarity and an intensity of an applied voltage, and
the plurality of self-selecting memory layers are configured to have different threshold voltages from each other, so that each of the plurality of memory cells implements a multilevel memory.

2. The 3D memory device of claim 1, wherein the transistor further comprises:
at least one gate electrode on the at least one channel layer; and
at least one gate insulating layer between the at least one channel layer and the at least one gate electrode.

3. The 3D memory device of claim 1, wherein each of the plurality of self-selecting memory layers comprises:
a chalcogen element including at least one of Se, Te, and S; and
at least one of Ge, As, and Sb.

4. The 3D memory device of claim 1, wherein the plurality of self-selecting memory layers are connected to the transistor in parallel or in series.

5. The 3D memory device of claim 4, wherein
the plurality of self-selecting memory layers comprise a first self-selecting memory layer having a first reset threshold voltage and a second self-selecting memory layer having a second reset threshold voltage, and
a magnitude of the second reset threshold voltage is higher than a magnitude of the first reset threshold voltage.

6. The 3D memory device of claim 5, wherein
the plurality of memory cells are configured to implement multilevel resistance states by changing a voltage applied to each of the first self-selecting memory layer and the second self-selecting memory layer.

7. The 3D memory device of claim 6, wherein
the plurality of memory cells are configured to implement the multilevel resistance states by changing the voltage applied to each of the first self-selecting memory layer and the second self-selecting memory layer to a voltage with a magnitude lower than the magnitude of the first reset threshold voltage, a voltage between the first reset threshold voltage and the second reset threshold voltage, and a voltage with a magnitude higher than the magnitude of the second reset threshold voltage,
the first reset threshold voltage is between the second reset threshold voltage and the voltage with the magnitude less than the magnitude of the first reset threshold voltage, and
the second reset threshold voltage is between the first reset threshold voltage and the voltage with the magnitude higher than the magnitude of the second reset threshold voltage.

8. The 3D memory device of claim 1, further comprising:
a plurality of bit lines extending perpendicular to the substrate, wherein
the plurality of memory cells are arranged perpendicular to the substrate along the plurality of bit lines.

9. The 3D memory device of claim 8, further comprising:
a plurality of word lines extending parallel to the substrate and intersecting the plurality of bit lines.

10. The 3D memory device of claim 1, further comprising:
a plurality of bit lines extending perpendicular to the substrate; and
a plurality of select lines on the substrate, wherein
the plurality of select lines are configured to select a selected bit line among the plurality of bit lines.

11. An electronic apparatus comprising:
the three-dimensional (3D) memory device of claim 1.

12. A method of implementing a multilevel memory by using a three-dimensional (3D) memory device, the 3D memory device comprising a plurality of memory cells arranged in three dimensions on a substrate, the method comprising:
implementing multi-level resistance states by changing a voltage applied to a plurality of self-selecting memory layers in the plurality of memory cells,
wherein each of the plurality of memory cells comprises the plurality of self-selecting memory layers connected to a transistor,
the transistor includes at least one channel layer parallel to the substrate,
each of the plurality of self-selecting memory layers includes a chalcogenide-based material having Ovonic threshold switching characteristics, and
a threshold voltage of the chalcogenide-based material changes according to a polarity and an intensity of an applied voltage.

13. The method of claim 12, wherein the plurality of self-selecting memory layers are connected to the transistor in parallel or in series.

14. The method of claim 13, wherein the plurality of self-selecting memory layers configured to have different threshold voltages from each other.

15. The method of claim 14, wherein
the plurality of self-selecting memory layers comprise a first self-selecting memory layer having a first reset threshold voltage and a second self-selecting memory layer having a second reset threshold voltage, and
a magnitude of the second reset threshold voltage is higher than a magnitude of the first reset threshold voltage.

16. The method of claim 15, wherein
the multi-level resistance states are implemented by changing a voltage applied to each of the first self-selecting memory layer and the second self-selecting memory layer to a voltage with a magnitude lower than the magnitude of first reset threshold voltage, a voltage between the first reset threshold voltage and the second reset threshold voltage, or a voltage with a magnitude higher than the magnitude of the second reset threshold voltage,
the first reset threshold voltage is between the second reset threshold voltage and the voltage with the magnitude less than the magnitude of the first reset threshold voltage, and
the second reset threshold voltage is between the first reset threshold voltage and the voltage with the magnitude higher than the magnitude of the second reset threshold voltage.

17. The method of claim 12, wherein
the transistor further comprises at least one gate electrode on the at least one channel layer and at least one gate insulating layer between the at least one channel layer and the at least one gate electrode.

18. The method of claim 12, wherein
the 3D memory device further comprises a plurality of bit lines extending perpendicular to the substrate, and
the plurality of memory cells are arranged perpendicular to the substrate along the plurality of bit lines.

19. The method of claim 18, wherein
the 3D memory device further comprises a plurality of word lines extending parallel to the substrate and intersecting the plurality of bit lines.

20. The method of claim 19, wherein
the 3D memory device further comprises a plurality of bit lines extending perpendicular to the substrate,
the 3D memory device further comprises a plurality of select lines on the substrate, and
the plurality of select lines are configured to select a selected bit line among the plurality of bit lines.
